(19) United States
(12) Patent Application Publication
(10) Pub. No.: US 2011/0052794 A1
(43) Pub. Date: Mar. 3, 2011

(54) VAPOR-PHASE GROWTH APPARATUS AND THIN-FILM VAPOR-PHASE GROWTH METHOD

(75) Inventor: Toru Yamada, Annaka (JP)

(73) Assignee: SHIN-ETSU HANDOTAI CO., LTD., TOKYO (JP)

(21) Appl. No.: 12/991,796

(22) PCT Filed: Apr. 22, 2009
(86) PCT No.: PCT/JP2009/001833

§ 371 Date: Nov. 9, 2010

(30) Foreign Application Priority Data
May 12, 2008 (JP) 2008-125106

(51) Int. Cl. B05D 5/12; C23C 16/455

(52) U.S. Cl. 427/58; 118/696; 118/699

(57) ABSTRACT

A method for vapor-phase growth of a thin film by introducing into a reaction chamber a raw material gas wherein a dilute impurity gas, having a mixture of impurity gas of which the flow-rate is controlled by a first flow-rate controlling mechanism and diluting gas of which the flow-rate is controlled by a second flow-rate controlling mechanism, of which mixture the flow-rate is controlled by a third flow-rate controlling mechanism is mixed with a main gas of which the flow-rate is controlled by a fourth flow-rate controlling mechanism, and vapor-phase growth is carried out by supplying the raw material gas to the reaction chamber while changing continuously and simultaneously with arithmetic control the flow-rates of the gases flowing through said first, second and third flow-rate controlling mechanisms so that the resistivity distribution is controlled and a required resistivity profile is achieved in the thickness direction of the thin film.

### TECHNICAL FIELD

The present invention relates to a vapor-phase growth apparatus and a thin-film vapor-phase growth method, and particularly to: a vapor-phase growth apparatus capable of vapor-phase growth a thin-film having a continuously changed impurity concentration, a thin-film having an impurity concentration largely changed in a thickness direction, or the like; and a thin-film vapor-phase growth method.

### BACKGROUND ART

In case of a standard vapor-phase growth apparatus 30 as shown in FIG. 5, the apparatus comprises a reaction chamber 42 for conducting vapor-phase growth therein, a flow passage 31 for introducing a raw material gas into the reaction chamber 42, an exhaust port for exhausting a gas from the reaction chamber 42, and a susceptor for placing a wafer W thereon. Further, processing for the vapor-phase growth is executed by providing an operational controlling unit 41 of the vapor-phase growth apparatus 30, with information, which describes a processing procedure called “recipe”.

This recipe is divided into several steps for wafer loading, temperature elevation, pretreatment, vapor-phase growth, drop in temperature, wafer unloading, and the like, in a manner to describe an opening/closing instruction of valves, flow rate setting values for massflow controllers, and the like for each step, thereby causing the massflow controllers 32, 34, 36, and 38 to adjust flow rates of an impurity gas, a dilution gas, a diluted impurity gas, and a main gas, respectively, based on this information.

In such a configuration, flow rate setting values for all the massflow controllers are constant during conduction of vapor-phase growth of a thin-film as shown in FIG. 6, so that an impurity concentration of a produced thin-film is also made constant from commencement of the growth to termination of the growth.

If it is intended to obtain a vapor-phase grown thin-film having the concentration continuously changed from the commencement of the growth of the thin-film to the termination of the growth by means of the vapor-phase growth apparatus having such a configuration, it has been inevitable to divide a step of vapor-phase growth into numerous sub-steps in a manner to prepare a stepwise concentration distribution therefrom and to substitutionally use it.

Depending on types of apparatuses, such an apparatus is found where setting values for massflow controllers are set to be linearly changed relative to a time from the first of the step to the last of the step.

In this case, it is possible to adopt setting values for massflow controllers described in a vapor-phase growth step as setting values at the commencement of the step, respectively, and to adopt setting values for the massflow controllers described in the next step as values at the termination of the vapor-phase growth step, in a manner to allow the setting values to be changed moment by moment within the single step of vapor-phase growth.

Unfortunately, even by the apparatus as set in this way, the changing manner of the setting values for the respective massflow controllers is restricted to a linear change relative to a time, thereby failing to grow a thin-film having an arbitrary impurity concentration distribution in a thickness direction of the thin-film.

In view of the progress of computer technique today, it is not impossible to: describe a data in a vapor-phase growth step of a recipe so as to change setting values for massflow controllers moment by moment; and execute the step. However, standard vapor-phase growth apparatuses each have the above specified configuration.

For example, in case of intending to linearly change an impurity concentration in a silicon epitaxial layer from 1 at the commencement of growth down to 1/50 at the termination of growth to thereby cause the layer to have a resistivity distribution in a thickness direction thereof, it might appear to be enough to linearly change an impurity amount to be mixed in a main gas from 1 at the commencement of growth down to 1/50 at the termination. However, it is not enough to simply change the mixing amount of a diluted impurity gas into the main gas, while the mixing ratio between an impurity gas and a dilution gas is kept constant.

This is because, the range of a massflow controller, where the massflow controller is capable of adjusting a flow rate therethrough with a higher precision, is generally between 10% and 100% of a full scale, so that errors are so increased at flow rates of 10% or less. As such, the span of adjustable range of flow rate is up to about 10 times at the utmost, so that a change of resistivity has been restricted to about 1/10. It has been thus problematically difficult to fabricate a thin-film having a resistivity changed at a ratio larger than the above.

If it is intended to continuously change an impurity concentration of a diluted impurity gas as well, by changing a mixing ratio between an impurity gas and a dilution gas so as to cope with the above problem, two methods are in turn conceivable for mixing a required impurity amount into a main gas, i.e., a method to adjust the impurity amount by means of a concentration of the diluted impurity gas, and another method to adjust the impurity amount by means of a mixing amount of the diluted impurity gas into the main gas.

As a result, according to this conception, it becomes impossible to uniquely determine as to how the setting values of the three massflow controllers for an impurity gas, a dilution gas, and a diluted impurity gas are to be changed. It has been thus difficult to provide such a configuration to change setting values of three massflow controllers within the step of silicon epitaxial growth moment by moment.

Further, Japanese Patent Application Laid-open No. H5-308053 discloses a vapor-phase growth apparatus configured to measure a film thickness and an impurity concentration of a thin-film during vapor-phase growth thereof, and to compare the measured values with those in a database to thereby control flow rates of gases. However, the vapor-phase growth apparatus described in this Japanese Patent Application Laid-open No. H5-308053 is incapable of fabricating a thin-film having an impurity concentration largely changed in a thickness direction of the thin-film.

### DISCLOSURE OF THE INVENTION

The present invention has been carried out in view of the above problem, and it is therefore an object of the present invention to provide: a vapor-phase growth apparatus capable of readily vapor-phase growth a thin-film having an impurity concentration continuously changed in a thickness direction thereof, a thin-film having an impurity concentration largely changed in such a direction, or the like; and a thin-film vapor-phase growth method therefor.

To achieve the above object, the present invention provides a vapor-phase growth apparatus for placing a wafer on a susceptor and vapor-phase growth a thin-film on the wafer, comprising, at least:

a reaction chamber for conducting vapor-phase growth therein; a flow passage for introducing a raw material gas into the reaction chamber; an exhaust port for exhausting a gas from the reaction chamber; the susceptor for placing the wafer thereon; and heating units for heating the wafer;

wherein the flow passage comprises: an impurity gas supplying passage for supplying an impurity gas, and a first flow rate adjusting mechanism for adjusting a flow rate of the impurity gas; a dilution gas supplying passage for supplying a dilution gas, and a second flow rate adjusting mechanism for adjusting a flow rate of the dilution gas; a diluted impurity gas supplying passage for supplying a diluted impurity gas obtained by mixing the impurity gas and dilution gas both adjusted in flow rate, and a third flow rate adjusting mechanism for adjusting a flow rate of the diluted impurity gas; a main gas supplying passage for supplying a main gas, and a fourth flow rate adjusting mechanism for adjusting a flow rate of the main gas; and a raw material gas supplying passage for supplying a raw material gas, obtained by mixing the diluted impurity gas and main gas both adjusted in flow rate, into the reaction chamber; and

wherein the apparatus further comprises an arithmetic controlling unit capable of simultaneously and continuously changing flow rates of the gases through the first, second, and third flow rate adjusting mechanisms so that the thin-film exhibits a desired resistivity profile in a thickness direction thereof.

In this way, the vapor-phase growth apparatus of the present invention comprises the arithmetic controlling unit capable of simultaneously and continuously changing flow rates of the impurity gas, dilution gas, and diluted impurity gas so that the thin-film exhibits a desired resistivity profile in a thickness direction thereof.

Since the apparatus comprises such the arithmetic controlling unit, it is allowed to determine a certain relationship among the impurity gas flow rate, dilution gas flow rate, and diluted impurity gas flow rate, thereby enabling to uniquely prescribe the impurity gas flow rate and the impurity gas concentration corresponding to a required impurity amount. This enables to readily and simultaneously change, with a higher precision, the impurity gas flow rate, diluted impurity gas flow rate, and dilution gas flow rate so that the thin-film exhibits a desired resistivity profile in a thickness direction thereof; so that the vapor-phase growth apparatus can vapor-phase grow, on a wafer, a thin-film having a continuously changed impurity concentration, a thin-film having a largely changed impurity concentration (particularly at a ratio of 10 times or more), and the like, each in a thickness direction of the applicable thin-film, irrespectively of accuracy limitations of flow rate control of the flow rate adjusting mechanisms.

Here, it is preferable that the arithmetic controlling unit is configured to use an impurity profile of the thin-film, which impurity profile is prescribed by an impurity gas flow rate, a dilution gas flow rate, and a mixing amount of diluted impurity gas into a main gas each upon commencement of growth of the thin-film, and by an impurity gas flow rate, a dilution gas flow rate, and a mixing amount of diluted impurity gas into a main gas each upon termination of growth of the thin-film, to thereby simultaneously and continuously change flow rates of the gases through the first, second, and third flow rate adjusting mechanisms, respectively.

In this way, the arithmetic controlling unit is configured to use the impurity concentration profile which is prescribed by an impurity gas flow rate, a dilution gas flow rate, and a mixing amount of diluted impurity gas into a main gas each upon commencement of growth of the thin-film, and by an impurity gas flow rate, a dilution gas flow rate, and a mixing amount of diluted impurity gas into a main gas each upon termination of growth; so that the vapor-phase growth apparatus can prescribe impurity concentrations of the thin-film at a wafer side and a front surface side thereof, respectively, thereby enabling to readily vapor-phase grow a thin-film exhibiting a desired resistivity profile.

Further, it is possible that the arithmetic controlling unit is further configured to use the impurity concentration profile to be prescribed by selecting one or more pairs of the value of impurity concentration of the thin-film and the elapsed time from the commencement of growth, thereby changing the gas flow rates.

In this way, the arithmetic controlling unit is further configured to use, as the impurity concentration profile, that profile to be prescribed by selecting one or more pairs of the value of impurity concentration of the thin-film and the elapsed time from the commencement of growth, in addition to the values of the impurity concentration upon commencement of growth and upon termination of growth; so that the vapor-phase growth apparatus can prescribe an impurity concentration at a certain thickness between the wafer side and the front surface side of the thin-film, thereby enabling to more readily vapor-phase grow, on the wafer, the thin-film exhibiting the desired resistivity profile through the interior of the thin-film as well.

Furthermore, it is possible that the arithmetic controlling unit is further configured to interpolate, by a straight line or curved line, between: the above selected value; the impurity concentration upon commencement of growth of the thin-film, to be prescribed by the impurity gas flow rate, the dilution gas flow rate, and the mixing amount of diluted impurity gas into the main gas each upon commencement of growth of the thin-film; and the impurity concentration upon termination of growth of the thin-film, to be prescribed by the impurity gas flow rate, the dilution gas flow rate, and the mixing amount of diluted impurity gas into the main gas each upon termination of growth of the thin-film.

In this way, the arithmetic controlling unit is further configured to use the impurity concentration profile prescribed by interpolating, by the straight line or curved line, between the above selected value, and impurity concentrations upon commencement of growth and upon termination of growth of the thin-film, thereby enabling to more readily vapor-phase grow, with a higher precision on the wafer, a thin-film exhibiting the desired resistivity profile through the interior of the thin-film as well.

It is possible that the arithmetic controlling unit is further configured to change the gas flow rates by using the impurity concentration profile prescribed by a function connecting between: the impurity concentration upon commencement of growth of the thin-film, to be prescribed by the impurity gas flow rate, the dilution gas flow rate, and the mixing amount of diluted impurity gas into the main gas each upon commencement of growth of the thin-film; and the impurity concentration upon termination of growth of the thin-film, to be prescribed by the impurity gas flow rate, the dilution gas flow rate, and the mixing amount of diluted impurity gas into the main gas each upon termination of growth of the thin-film.

In this way, the arithmetic controlling unit is configured to use the impurity concentration profile prescribed by the function connecting between the impurity concentrations upon commencement of growth and upon termination of growth of the thin-film, thereby enabling to prescribe the impurity concentration profile within the interior of the thin-film with a higher precision i.e., to vapor-phase grow, on a wafer, a thin-film exhibiting a desired resistivity profile over the whole interior of the thin-film with a higher precision.

Further, the present invention provides a thin-film vapor-phase growth method for placing a wafer on a susceptor of a reaction chamber and vapor-phase growth a thin-film on the wafer, comprising, at least the steps of:

introducing a raw material gas into the reaction chamber; the raw material gas being obtained by mixing a diluted impurity gas the flow rate of which is controlled by a third flow rate adjusting mechanism, with a main gas the flow rate of which is controlled by a fourth flow rate adjusting mechanism; the diluted impurity gas being obtained by mixing an impurity gas the flow rate of which is controlled by a first flow rate adjusting mechanism, with a dilution gas the flow rate of which is controlled by a second flow rate adjusting mechanism; and

simultaneously and continuously changing the flow rates of the gases flowing through the first, second, and third flow rate adjusting mechanisms by an arithmetic control such that the thin-film exhibits a desired resistivity profile in a thickness direction thereof, to conduct vapor-phase growth while supplying the raw material gas into the reaction chamber, thereby controlling a resistivity distribution of the thin-film in a thickness direction thereof.

In this way, the flow rates of an impurity gas, a dilution gas, and a diluted impurity gas are arithmetically controlled and simultaneously and continuously changed so that a thin-film to be vapor-phase grown exhibits a desired resistivity profile in a thickness direction thereof, in a manner to conduct vapor-phase growth while supplying a raw material gas into a reaction chamber; thereby vapor-phase growth the thin-film while controlling the resistivity distribution of the thin-film in a thickness direction thereof.

This enables to readily and simultaneously change, with a higher precision, the impurity gas flow rate, diluted impurity gas flow rate, and dilution gas flow rate so that the thin-film exhibits a desired resistivity profile in a thickness direction thereof; thereby enabling to vapor-phase grow, on a wafer, a thin-film having a continuously changed impurity concentration, a thin-film having a largely changed impurity concentration, and the like, each in a thickness direction of the applicable thin-film.

Here, it is preferable that the arithmetic control is configured to use an impurity concentration profile of the thin-film, which impurity concentration profile is prescribed, at least, by an impurity gas flow rate, a dilution gas flow rate, and a mixing amount of diluted impurity gas into a main gas each upon commencement of growth of the thin-film, and by an impurity gas flow rate, a dilution gas flow rate, and a mixing amount of diluted impurity gas into a main gas each upon termination of growth of the thin-film, to thereby simultaneously and continuously change flow rates of the gases flowing through the first, second, and third flow rate adjusting mechanisms, respectively.

In this way, by prescribing impurity concentrations of the thin-film upon commencement of growth and upon termination of growth thereof, it is enabled to prescribe impurity concentrations of the thin-film at a wafer side and a front surface side thereof, respectively, thereby enabling to readily vapor-phase grow a thin-film exhibiting a desired resistivity profile.

Furthermore, it is possible that the arithmetic control is further configured to use the impurity concentration profile to be prescribed by selecting one or more pairs of a value of impurity concentration of the thin-film and an elapsed time from the commencement of growth, thereby changing the gas flow rates.

In this way, the arithmetic control is conducted to use, as the impurity concentration profile, that profile to be prescribed by selecting one or more pairs of the value of impurity concentration of the thin-film and the elapsed time from the commencement of growth, in addition to the values of the impurity concentration upon commencement of growth and upon termination of growth; to enable to prescribe an impurity concentration at a certain thickness between the wafer side and the front surface side of the thin-film, thereby enabling to more readily vapor-phase grow, on the wafer, the thin-film exhibiting the desired resistivity profile through the interior of the thin-film as well.

Moreover, it is possible that the arithmetic control is configured to change the gas flow rates by using the impurity concentration profile prescribed by interpolating, by a straight line or curved line, between: the above selected value; the impurity concentration upon commencement of growth of the thin-film, to be prescribed by the impurity gas flow rate, the dilution gas flow rate, and the mixing amount of diluted impurity gas into the main gas each upon commencement of growth of the thin-film; and the impurity concentration upon termination of growth of the thin-film, to be prescribed by the impurity gas flow rate, the dilution gas flow rate, and the mixing amount of diluted impurity gas into the main gas each upon termination of growth of the thin-film.

In this way, the arithmetic control is configured to control the gas flow rates in accordance with an impurity concentration profile obtained by interpolating, by the straight line or curved line, between the above selected impurity concentration, and impurity concentrations upon commencement of growth and upon termination of growth, thereby enabling to more readily vapor-phase grow, with a higher precision on the wafer, a thin-film exhibiting a desired resistivity profile through the interior of the thin-film as well.

Further, it is possible that the arithmetic control is further configured to change the gas flow rates by using the impurity concentration profile prescribed by a function connecting between: the impurity concentration upon commencement of growth of the thin-film, to be prescribed by the impurity gas flow rate, the dilution gas flow rate, and the mixing amount of diluted impurity gas into the main gas each upon commencement of growth of the thin-film; and the impurity concentration upon termination of growth of the thin-film, to be prescribed by the impurity gas flow rate, the dilution gas flow rate, and the mixing amount of diluted impurity gas into the main gas each upon termination of growth of the thin-film.

In this way, by connecting between the impurity concentrations of the thin-film upon commencement of growth and upon termination of growth by the function, it is enabled to prescribe, with a higher precision, the impurity concentration profile between the wafer side and the front surface side of the thin-film; and by conducting the control by using the impurity concentration profile, it is enabled to vapor-phase grow, on the wafer, a thin-film exhibiting a desired resistivity profile over the whole interior of the thin-film with a higher precision.

According to the vapor-phase growth apparatus and the thin-film vapor-phase growth method of the present invention, the respective flow rates of the impurity gas, dilution gas, and diluted impurity gas corresponding to a required impurity amount can be changed moment by moment with a higher precision upon vapor-phase growth, to thereby enable to change a mixing ratio between the impurity gas and the dilution gas to continuously change an impurity concentration in the diluted impurity gas as well, so that a thin-film can be fabricated which realizes an impurity concentration change of 10 times or more (about 1,000 times, for example) in a thickness direction of the thin-film, thereby enabling to fabricate a thin-film having an arbitrary resistivity profile in a thickness direction thereof.

### BRIEF DESCRIPTION OF THE DRAWINGS

FIG. 1 is a schematic view of a structure of a vapor-phase growth apparatus according to an embodiment of the present invention;

FIG. 2 is a graph of an example of flow rate changes in flow rate adjusting mechanisms of the vapor-phase growth apparatus according to the present invention;

FIG. 3 is a graph of flow rate changes of three massflow controllers in the embodiment according to the present invention, relative to a time from a commencement of growth;

FIG. 4 is a graph of an evaluation result of a carrier concentration of an epitaxial layer in a thickness direction thereof in an Example of the present invention;

FIG. 5 is a schematic view of an example of a structure of a conventional vapor-phase growth apparatus; and

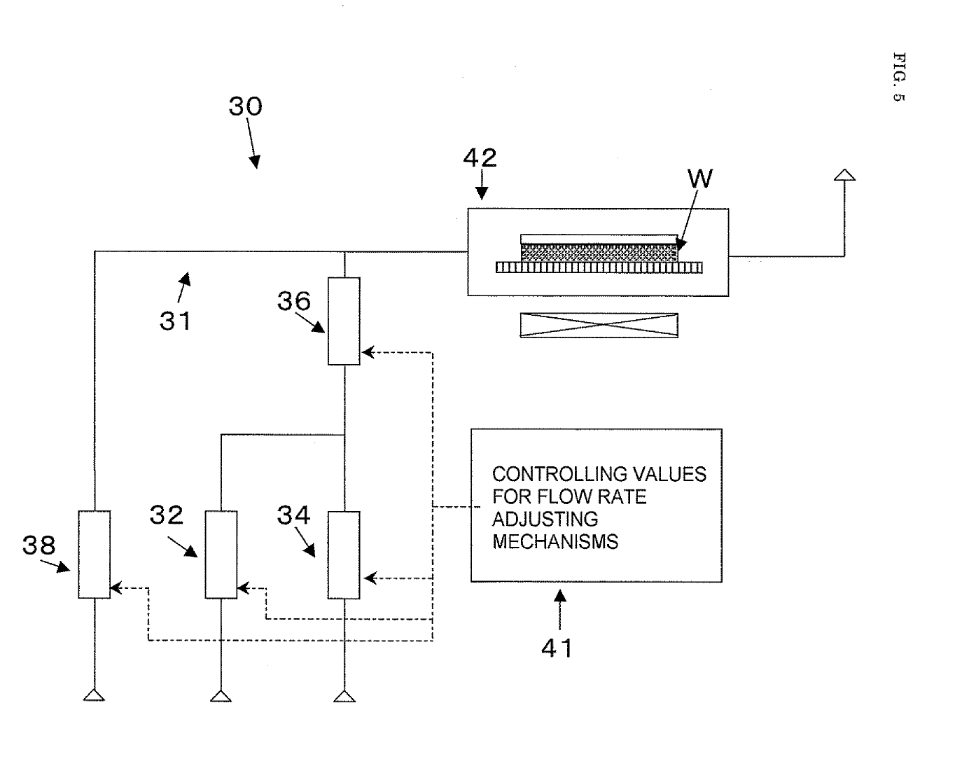

FIG. 6 is a graph of an example of flow rate changes in flow rate adjusting mechanisms of the conventional vapor-phase growth apparatus.

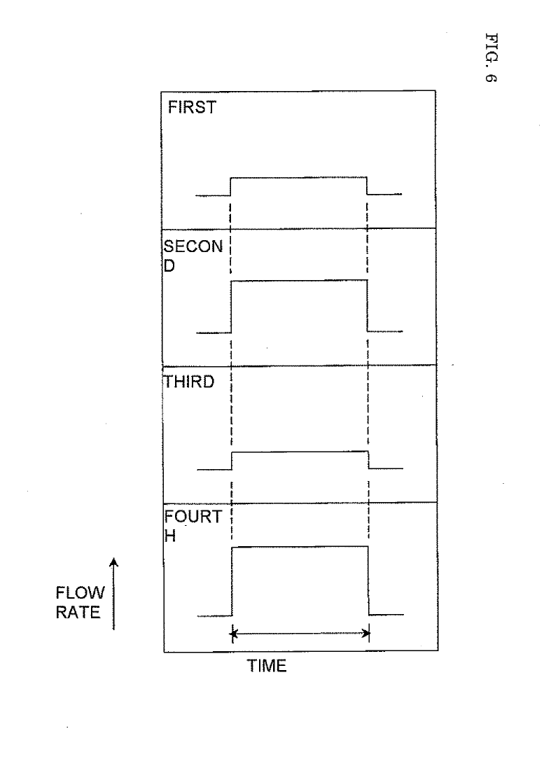

### BEST MODE FOR CARRYING OUT THE INVENTION

The present invention will be described more specifically hereinafter.

As described above, development has been eagerly desired for a vapor-phase growth apparatus and a vapor-phase growth method, capable of readily vapor-phase growth a thin-film having a continuously changed impurity concentration, a thin-film having a largely changed impurity concentration, and the like, and particularly a thin-film having a resistivity changed at a ratio of 10 times or more, each in a thickness direction of the applicable thin-film.

As such, the present inventor have earnestly and repetitively conducted investigations, and resultingly conceived that: by arithmetically controlling and simultaneously and continuously changing flow rates of an impurity gas, a dilution gas, and a diluted impurity gas while determining a certain relationship among the flow rates so that a thin-film to be vapor-phase grown exhibits a desired resistivity profile in a thickness direction thereof, in a manner to conduct vapor-phase growth while supplying a raw material gas into a reaction chamber; it is enabled to continuously change an impurity concentration of the diluted impurity gas as well while changing a mixing ratio between the impurity gas and the dilution gas thereby enabling to vapor-phase grow a thin-film having a continuously changed impurity concentration, a thin-film having a largely changed impurity concentration, and the like, each in a thickness direction of the applicable thin-film; to thereby completed the present invention.

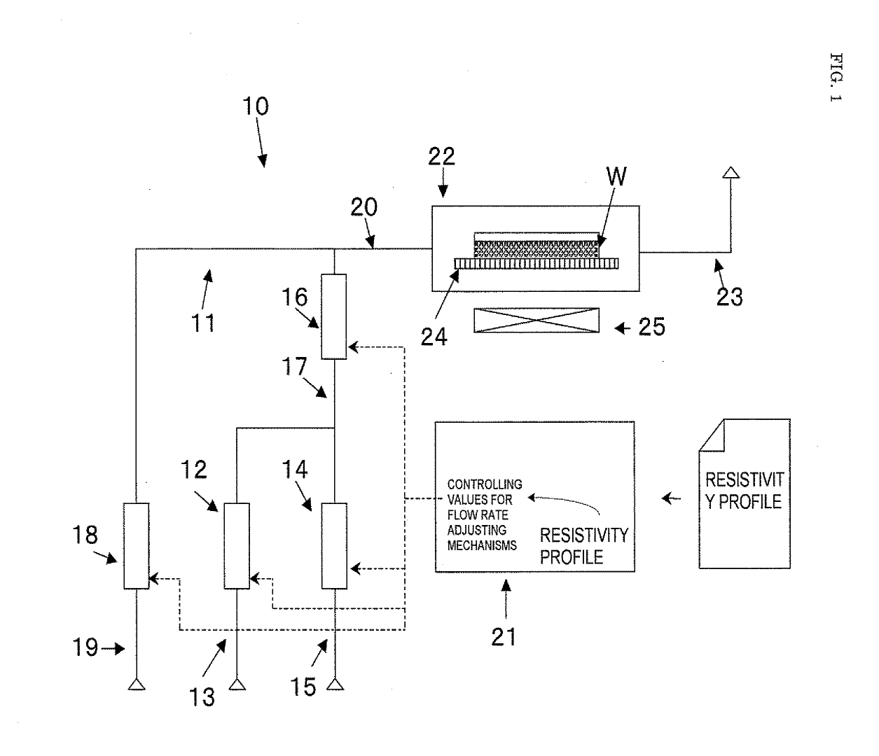

Hereinafter, the present invention will be explained more in detail referring to attached figures. However, the present invention is not restricted thereto. FIG. 1 is a schematic view of a structure of a vapor-phase growth apparatus according to an embodiment of the present invention.

The vapor-phase growth apparatus 10 of the present invention comprises, at least: a reaction chamber 22 for conducting vapor-phase growth therein; a flow passage 11 for introducing a raw material gas into the reaction chamber 22; an exhaust port 23 for exhausting a gas from the reaction chamber 22; a susceptor 24 for placing a wafer W thereon; and heating units 25 for heating the wafer W.

Further, the flow passage 11 comprises: an impurity gas supplying passage 13 for supplying an impurity gas, and a first flow rate adjusting mechanism 12 for adjusting a flow rate of the impurity gas; a dilution gas supplying passage 15 for supplying a dilution gas, and a second flow rate adjusting mechanism 14 for adjusting a flow rate of the dilution gas; a diluted impurity gas supplying passage 17 for supplying a diluted impurity gas obtained by mixing the impurity gas and dilution gas both adjusted in flow rate, and a third flow rate adjusting mechanism 16 for adjusting a flow rate of the diluted impurity gas; a main gas supplying passage 19 for supplying a main gas, and a fourth flow rate adjusting mechanism 18 for adjusting a flow rate of the main gas; and a raw material gas supplying passage 20 for supplying a raw material gas, obtained by mixing the diluted impurity gas and main gas both adjusted in flow rate, into the reaction chamber.

The apparatus further comprises an arithmetic controlling unit 21 capable of simultaneously and continuously changing flow rates of the gases through the first, second, and third flow rate adjusting mechanisms 12, 14, and 16 so that a thin-film exhibits a desired resistivity profile in a thickness direction thereof.

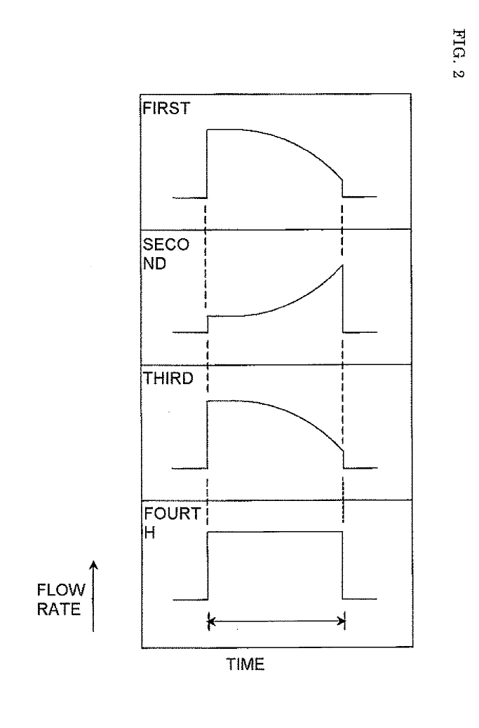

FIG. 2 is a graph of an example of flow rate changes in the respective flow rate adjusting mechanisms of the vapor-phase growth apparatus 10 as shown in FIG. 1. In FIG. 2, the abscissa represents a time and the ordinate represents a flow rate, and FIG. 2 shows flow rate changing patterns of the first, second, third, and fourth flow rate adjusting mechanisms in the order in a top-down direction.

In this way, the vapor-phase growth apparatus 10 comprising the arithmetic controlling unit 21 capable of simultaneously and continuously changing the flow rates of the gases through the first, second, and third flow rate adjusting mechanisms 12, 14, and 16 so that a thin-film exhibits a desired resistivity profile in a thickness direction thereof, is capable of changing an impurity gas concentration in the raw material gas to be supplied into the reaction chamber 22, moment by moment with a higher precision upon vapor-phase growth. This enables to continuously change an impurity profile of a thin-film to be fabricated, in a thickness direction thereof. Further, since the vapor-phase growth apparatus is configured to continuously and simultaneously control an impurity gas concentration in the raw material gas by the multiple flow rate adjusting mechanisms, it is possible to adjust the impurity gas concentration without depending on a width of adjustable range of each flow rate adjusting mechanism itself, unlike the conventional. This enables to change a resistivity profile of a thin-film to be fabricated, in a thickness direction thereof, at a ratio larger than the conventional, thereby enabling to obtain a wafer formed with a thin-film by vapor-phase growth, which thin-film exhibits a resistivity largely changed in a thickness direction thereof.

Here, the arithmetic controlling unit 21 is capable of using an impurity profile of a thin-film, which impurity profile is prescribed by an impurity gas flow rate, a dilution gas flow rate, and a mixing amount of diluted impurity gas into a main gas each upon commencement of growth of the thin-film, and by an impurity gas flow rate, a dilution gas flow rate, and a mixing amount of diluted impurity gas into a main gas each upon termination of growth of the thin-film, to thereby simultaneously and continuously change flow rates of the gases through the first, second, and third flow rate adjusting mechanisms 12, 14, and 16.

This enables to prescribe the impurity concentrations of the thin-film to be fabricated upon commencement of growth and upon termination of growth, thereby enabling to prescribe an impurity concentration profile of the supply gas in such a manner to provide a vapor-phase grown resistivity profile having desired resistivities upon commencement of growth and upon termination of growth to be determined by a specified configuration, for example. This allows the flow rates of gases through the first, second, and third flow rate adjusting mechanisms, to be simultaneously and continuously changed more readily so as to achieve the desired resistivity profile.

Further, the arithmetic controlling unit 21 is capable of using the impurity concentration profile to be prescribed by selecting one or more pairs of a value of impurity concentration of the thin-film and an elapsed time from the commencement of growth, thereby changing the gas flow rates.

In this way, it is possible to vapor-phase grow a thin-film having a desired resistivity profile more readily, because it is possible to more readily prescribe an impurity concentration profile of the supply gas for establishing a resistivity profile not only of surfaces of a thin-film to be fabricated but also of the interior of the thin-film in a more desirable manner by prescribing impurity concentrations at one or more arbitrary points in a thickness direction of the thin-film in addition to the values of impurity concentration of the thin-film upon commencement of growth and upon termination of growth.

Furthermore, the arithmetic controlling unit 21 is capable of changing the gas flow rates by using impurity concentration profile prescribed by interpolating, by a straight line or curved line, between: the above selected value; the impurity concentration upon commencement of growth of the thin-film, to be prescribed by the impurity gas flow rate, the dilution gas flow rate, and the mixing amount of diluted impurity gas into the main gas each upon commencement of growth of the thin-film; and the impurity concentration upon termination of growth of the thin-film, to be prescribed by the impurity gas flow rate, the dilution gas flow rate, and the mixing amount of diluted impurity gas into the main gas each upon termination of growth of the thin-film.

Moreover, by using the impurity concentration profile prescribed by interpolating between the value of impurity concentration upon commencement of growth of the thin-film, the selected value of impurity concentration, and the value of impurity concentration upon termination of growth of the thin-film to thereby simultaneously and continuously change the flow rates of gases through the first, second, and third flow rate adjusting mechanisms, it is enabled to prescribe, more readily and with a higher precision, an impurity concentration profile of the supply gas for establishing a resistivity profile of the thin-film in a more desirable manner.

Further, the arithmetic controlling unit 21 is capable of changing the gas flow rates by using the impurity concentration profile prescribed by a function connecting between: the impurity concentration upon commencement of growth of the thin-film, to be prescribed by the impurity gas flow rate, the dilution gas flow rate, and the mixing amount of diluted impurity gas into the main gas each upon commencement of growth of the thin-film; and the impurity concentration upon termination of growth of the thin-film, to be prescribed by the impurity gas flow rate, the dilution gas flow rate, and the mixing amount of diluted impurity gas into the main gas each upon termination of growth of the thin-film.

In this way, it is possible to make the vapor-phase growth apparatus to be capable of vapor-phase growth a thin-film having a desired resistivity profile with a higher precision, because it is possible to prescribe with a higher precision an impurity concentration profile of the supply gas for establishing a resistivity profile of the thin-film in a more desirable manner by using the impurity concentration profile obtained by prescribing, by the function, between the impurity concentrations upon commencement of growth and upon termination of growth of the thin-film, to thereby simultaneously and continuously change the flow rates of gases through the first, second, and third flow rate adjusting mechanisms, respectively.

Next, the thin-film vapor-phase growth method of the present invention will be explained which grows a thin-film on a wafer W by using the above-described vapor-phase growth apparatus 10, the present invention is not limited thereto of course.

Firstly, a wafer W is placed on the susceptor 24 and air in the reaction chamber 22 is evacuated therefrom, and then the wafer W is heated by the heating units 25 and a raw material gas is supplied into the reaction chamber thereby vapor-phase growth a thin-film on the wafer W.

Further, upon vapor-phase growth, flow rate of an impurity gas is controlled by the first flow rate adjusting mechanism 12 and flow rate of a dilution gas is controlled by the second flow rate adjusting mechanism 14, to prepare a diluted impurity gas. The flow rate of the thus prepared diluted impurity gas is controlled by the third flow rate adjusting mechanism 16, and the diluted impurity gas is mixed with a main gas the flow rate of which is controlled by the fourth flow rate adjusting mechanism 18, to thereby prepare a raw material gas, which is introduced into the reaction chamber 22.

At this time, at least the flow rates of gases flowing through the first, second, and third flow rate adjusting mechanisms 12, 14, and 16 are simultaneously and continuously changed by the arithmetic controlling unit 21 while being arithmetically controlled thereby so that the thin-film exhibits a desired resistivity profile in a thickness direction thereof, in a manner to supply the raw material gas into the reaction chamber 22, thereby conducting vapor-phase growth.

It is preferable to use a recipe including a processing procedure described therein as described above, for this arithmetic control.

In the present invention, this recipe includes an opening/closing of valves, flow rate setting values for massflow controllers, and the like directly described in the recipe similarly to a conventional vapor-phase growth apparatus, except for the vapor-phase growth step. Then, only the vapor-phase growth step includes, not setting values for the flow rate adjusting mechanisms, but such information recorded in the vapor-phase growth step in a manner to cause a thin-film to exhibit a desired resistivity profile.

Further, actual setting values for the respective flow rate adjusting mechanisms are obtained by the information of the recipe by the arithmetic controlling unit, and based on these values, flow rates of gases flowing through the first, second, and third flow rate adjusting mechanisms are simultaneously and continuously adjusted to vapor-phase grow a thin-film while controlling a resistivity distribution in a thickness direction thereof.

At this time, as a control method by the arithmetic controlling unit, it is possible to use an impurity concentration profile including impurity concentrations of a thin-film upon commencement of growth and upon termination of growth as prescribed by an impurity gas flow rate, a dilution gas flow rate, and a mixing amount of diluted impurity gas into a main gas, respectively, while prescribing that portion of the impurity concentration profile between the commencement and the termination, by enumerating pairs of a thickness-wise position and an impurity concentration of the thin-film, by interpolating between the commencement and termination by a straight line or curved line, or by prescribing the portion between the commencement and the termination by a function.

As a relationship for calculating control values of flow rates of the respective gases flowing through the first, second, and third flow rate adjusting mechanisms when the arithmetic controlling unit 21 uses the impurity concentration profile described in the recipe to thereby conduct arithmetic control, it is desirable to adopt the following relational equations, assuming that S represents a setting value of the massflow controller of the impurity gas, D represents a setting value of the massflow controller of the dilution gas, and I represents a setting value of the massflow controller for mixing the diluted impurity gas into the main gas (each setting value is supposed to become 0 when an applicable flow rate is zero, and 1 when the applicable flow rate is at a full scale), for example:

S=1.1−D(0.1<D<1.0) (equation 1)

I=S (equation 2)

At this time, it is more desirable to determine the relational equations in such a manner to be capable of representing all impurity supplying amounts continuously: from a combination of flow rate setting values capable of supplying the impurity in the largest amount which can be realized by the three flow rate adjusting mechanisms; to a combination of flow rate setting values capable of supplying the impurity in the smallest amount.

By the determination in the above manner, an amount X of an impurity to be mixed into the main gas is represented by the following equation, assuming that Cₛ represents a concentration of an impurity gas;

X=Cₛ×{(S×S_{f})/(S×S_{f}+D×D_{f})}×I×I_{f} (equation 3)

so that S, D, and I are uniquely determined from the (equation 1) to (equation 3) in a converse manner, when the amount X of impurity to be mixed into the main gas is determined. Here, S_{f} represents a full scale of the massflow controller of the impurity gas, D_{f} represents a full scale of the massflow controller of the dilution gas, and I_{f} represents a full scale of the massflow controller of the diluted impurity gas.

Further, the amount X of the impurity to be mixed into the main gas can be determined by an impurity concentration Cₑ of a thin-film desired to be grown. For example, when such an experimental result is provided that an impurity concentration of a completed silicon epitaxial layer is C_{eO} when flow rates of the massflow controllers are S_{O}, T_{O}, and D_{O}, respectively, the relationship between X and Cₑ can be represented as follows:

X=Cₛ×{(S_{O}×S_{f})/(S_{O}×S_{f}+D_{O}×D_{f})}×I_{O}×I_{f}×(Cₑ/C_{eO})

Thus, when the impurity concentration distribution Cₑ of the thin-film in a thickness direction thereof, and the experimental data S_{O}, I_{O}, D_{O}, and C_{eO} are provided by the recipe, the arithmetic controlling unit can uniquely determine the way to change the setting values S, D, and I of the three flow rate adjusting mechanisms, respectively.

At this time, several ways are conceivable, for describing the impurity concentration distribution Cₑ of the thin-film in a thickness direction thereof. The ways include one to enumerate pairs of a thickness-wise position and an impurity concentration of the thin-film, and another to prescribe an impurity concentration distribution by a mathematical equation.

Further, instead of designating the concentrations for the thin-film, it is possible to designate sets of an impurity gas flow rate, a dilution gas flow rate, and a mixing amount of diluted impurity gas into a main gas, required to obtain the concentrations for the thin-film, respectively.

In this way, according to the thin-film vapor-phase growth method of the present invention, flow rates of the impurity gas, the dilution gas, and the diluted impurity gas are arithmetically controlled and simultaneously and continuously changed while determining a certain relationship among the flow rates so that a thin-film to be vapor-phase grown exhibits a desired resistivity profile in a thickness direction thereof, in a manner to conduct vapor-phase growth while supplying a raw material gas into a reaction chamber; and it is thus enabled to continuously change the impurity concentration of the diluted impurity gas as well while changing the mixing ratio between the impurity gas and the dilution gas thereby enabling to arbitrarily vapor-phase grow the thin-film having the continuously changed impurity concentration, the thin-film having the largely changed impurity concentration, and the like, each in the thickness direction of the applicable thin-film.

### EXAMPLE

Hereinafter, the present invention will be explained in more detail based on Examples, but the present invention is not of course restricted thereto.

### Example

Using the vapor-phase growth apparatus 10 as shown in FIG. 1, a silicon thin-film was epitaxially grown on a silicon wafer such that the carrier concentration was linearly changed at a ratio of 30 times. At this time, four massflow controllers were prepared as the first through fourth flow rate adjusting mechanisms, respectively.

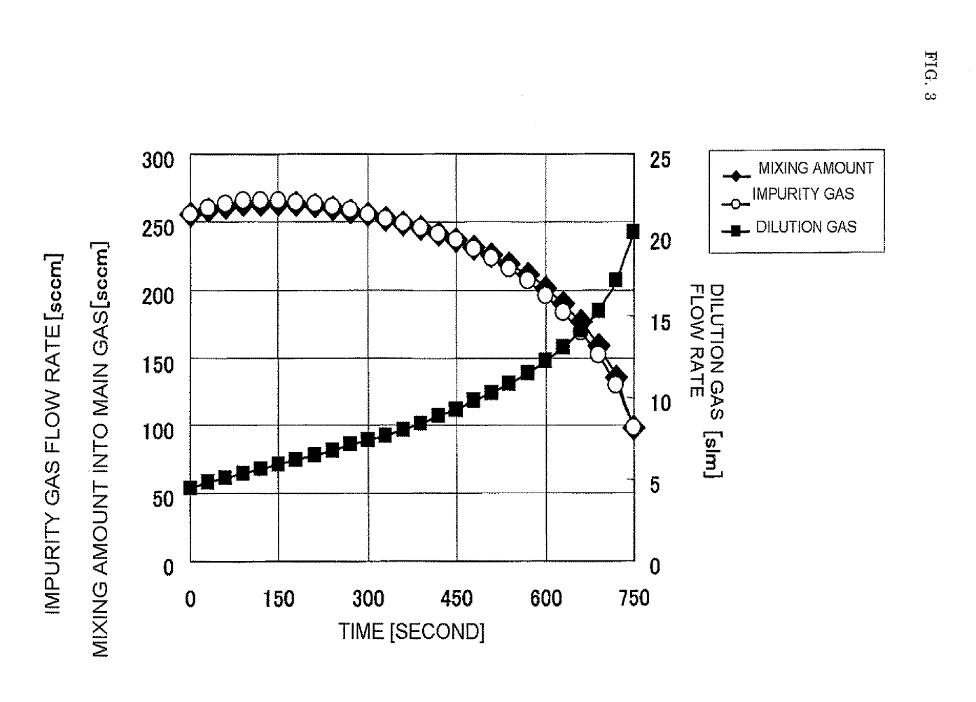

As a growing condition of a silicon thin-film, a silicon single crystal wafer having a diameter of 200 mm was used as a silicon wafer acting as a substrate. Further, used as a main gas was a mixed gas of 3% trichlorosilane and 97% hydrogen; hydrogen as a dilution gas; and a 1 ppm diborane gas as an impurity gas. Further, epitaxially grown on the silicon wafer was a silicon thin-film having a thickness of 50 μm. Then, the above-mentioned (equation 1) and (equation 2) were used as relational equations of the respective gases flowing through the first through third massflow controllers, respectively, thereby conducting epitaxial growth by flow rates as shown in FIG. 3.

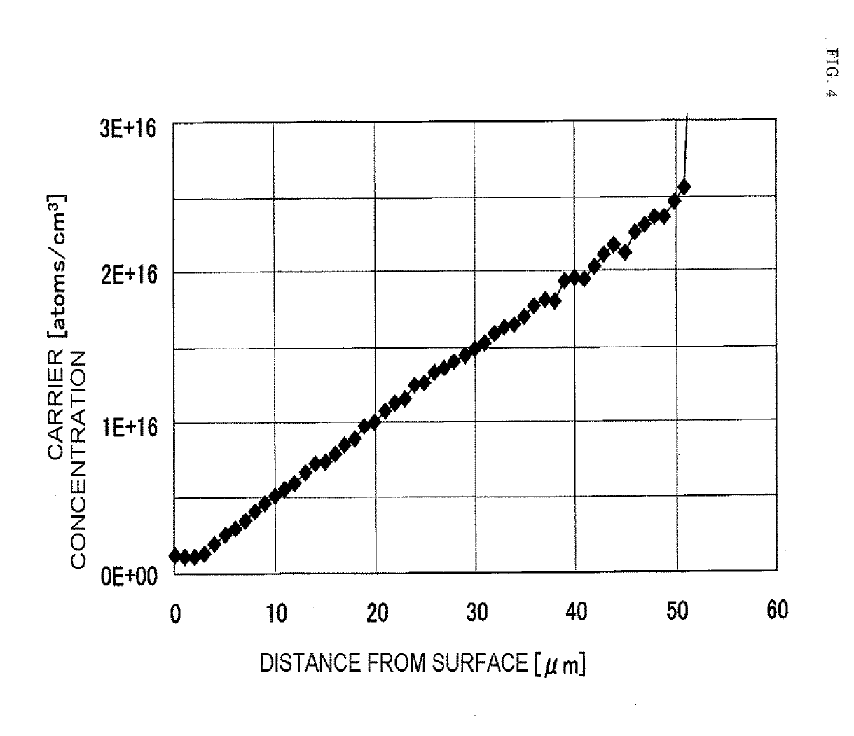

The carrier concentration of the thus fabricated silicon thin-film of the epitaxial wafer in a thickness direction thereof, was evaluated by an SR method. Actually measured values thereof are shown in FIG. 4.

It is thus recognized that, by using the three massflow controllers to simultaneously change the impurity gas, the dilution gas, and the diluted impurity gas as shown in FIG. 4, it is enabled to fabricate an epitaxial wafer having a silicon thin-film thereon the carrier concentration of which is changed at a ratio of as large as 30 times.

It is to be noted that the present invention is not restricted to the foregoing embodiment. The foregoing embodiment is just an exemplification, and any examples that have substantially the same configuration and exercise the same functions and effects as the technical concept described in claims according to the present invention are included in the technical scope of the present invention.

1. A vapor-phase growth apparatus for placing a wafer on a susceptor and vapor-phase growth a thin-film on the wafer, comprising, at least:
a reaction chamber for conducting vapor-phase growth therein; a flow passage for introducing a raw material gas into the reaction chamber; an exhaust port for exhausting a gas from the reaction chamber; the susceptor for placing the wafer thereon; and heating units for heating the wafer;
wherein the flow passage comprises: an impurity gas supplying passage for supplying an impurity gas, and a first flow rate adjusting mechanism for adjusting a flow rate of the impurity gas; a dilution gas supplying passage for supplying a dilution gas, and a second flow rate adjusting mechanism for adjusting a flow rate of the dilution gas; a diluted impurity gas supplying passage for supplying a diluted impurity gas obtained by mixing the impurity gas and dilution gas both adjusted in flow rate, and a third flow rate adjusting mechanism for adjusting a flow rate of the diluted impurity gas; a main gas supplying passage for supplying a main gas, and a fourth flow rate adjusting mechanism for adjusting a flow rate of the main gas; and a raw material gas supplying passage for supplying a raw material gas, obtained by mixing the diluted impurity gas and main gas both adjusted in flow rate, into the reaction chamber; and
wherein the apparatus further comprises an arithmetic controlling unit capable of simultaneously and continuously changing flow rates of the gases through the first, second, and third flow rate adjusting mechanisms so that the thin-film exhibits a desired resistivity profile in a thickness direction thereof.

2. The vapor-phase growth apparatus according to claim 1, wherein the arithmetic controlling unit is configured to use an impurity profile of a thin-film, which impurity profile is prescribed by an impurity gas flow rate, a dilution gas flow rate, and a mixing amount of diluted impurity gas into a main gas each upon commencement of growth of the thin-film, and by an impurity gas flow rate, a dilution gas flow rate, and a mixing amount of diluted impurity gas into a main gas each upon termination of growth of the thin-film, to thereby simultaneously and continuously change flow rates of the gases through the first, second, and third flow rate adjusting mechanisms, respectively.

3. The vapor-phase growth apparatus according to claim 2, wherein the arithmetic controlling unit is further configured to use the impurity concentration profile to be prescribed by selecting one or more pairs of a value of impurity concentration of the thin-film and an elapsed time from the commencement of growth, thereby changing the gas flow rates.

4. The vapor-phase growth apparatus according to claim 3, wherein the arithmetic controlling unit is further configured to change the gas flow rates by using the impurity concentration profile prescribed by interpolating, by a straight line or curved line, between: the above selected value; the impurity concentration upon commencement of growth of the thin-film, to be prescribed by the impurity gas flow rate, the dilution gas flow rate, and the mixing amount of diluted impurity gas into a main gas each upon commencement of growth of the thin-film; and the impurity concentration upon termination of growth of the thin-film, to be prescribed by the impurity gas flow rate, the dilution gas flow rate, and the mixing amount of diluted impurity gas into the main gas each upon termination of growth of the thin-film.

5. The vapor-phase growth apparatus according to claim 2, wherein the arithmetic controlling unit is further configured to change the gas flow rates by using the impurity concentration profile prescribed by a function connecting between: the impurity concentration upon commencement of growth of the thin-film, to be prescribed by the impurity gas flow rate, the dilution gas flow rate, and the mixing amount of diluted impurity gas into the main gas each upon commencement of growth of the thin-film; and the impurity concentration upon termination of growth of the thin-film, to be prescribed by the impurity gas flow rate, the dilution gas flow rate, and the mixing amount of diluted impurity gas into the main gas each upon termination of growth of the thin-film.

6. A thin-film vapor-phase growth method for placing a wafer on a susceptor of a reaction chamber and vapor-phase growth a thin-film on the wafer, comprising, at least the steps of:
introducing a raw material gas into the reaction chamber; the raw material gas being obtained by mixing a diluted impurity gas the flow rate of which is controlled by a third flow rate adjusting mechanism, with a main gas the flow rate of which is controlled by a fourth flow rate adjusting mechanism; the diluted impurity gas being obtained by mixing an impurity gas the flow rate of which is controlled by a first flow rate adjusting mechanism, with a dilution gas the flow rate of which is controlled by a second flow rate adjusting mechanism; and
simultaneously and continuously changing the flow rates of the gases flowing through the first, second, and third flow rate adjusting mechanisms by an arithmetic control such that the thin-film exhibits a desired resistivity profile in a thickness direction thereof, to conduct vapor-phase growth while supplying the raw material gas into the reaction chamber, thereby controlling a resistivity distribution of the thin-film in a thickness direction thereof.

7. The thin-film vapor-phase growth method according to claim 6, wherein the arithmetic control is configured to use an impurity concentration profile of the thin-film, which impurity concentration profile is prescribed, at least, by an impurity gas flow rate, a dilution gas flow rate, and a mixing amount of diluted impurity gas into a main gas each upon commencement of growth of the thin-film, and by an impurity gas flow rate, a dilution gas flow rate, and a mixing amount of diluted impurity gas into a main gas each upon termination of growth of the thin-film, to thereby simultaneously and continuously change flow rates of the gases flowing through the first, second, and third flow rate adjusting mechanisms, respectively.

8. The thin-film vapor-phase growth method according to claim 7, wherein the arithmetic control is further configured to use the impurity concentration profile to be prescribed by selecting one or more pairs of a value of impurity concentration of the thin-film and an elapsed time from the commencement of growth, thereby changing the gas flow rates.

9. The thin-film vapor-phase growth method according to claim 8, wherein the arithmetic control is configured to change the gas flow rates by using the impurity concentration profile prescribed by interpolating, by a straight line or curved line, between: the above selected value; the impurity concentration upon commencement of growth of the thin-film, to be prescribed by the impurity gas flow rate, the dilution gas flow rate, and the mixing amount of diluted impurity gas into the main gas each upon commencement of growth of the thin-film; and the impurity concentration upon termination of growth of the thin-film to be prescribed by the impurity gas flow rate, the dilution gas flow rate, and the mixing amount of diluted impurity gas into the main gas each upon termination of growth of the thin-film.

10. The thin-film vapor-phase growth method according to claim 7, wherein the arithmetic control is further configured to change the gas flow rates by using the impurity concentration profile prescribed by a function connecting between: the impurity concentration upon commencement of growth of the thin-film, to be prescribed by the impurity gas flow rate, the dilution gas flow rate, and the mixing amount of diluted impurity gas into the main gas each upon commencement of growth of the thin-film; and the impurity concentration upon termination of growth of the thin-film, to be prescribed by the impurity gas flow rate, the dilution gas flow rate, and the mixing amount of diluted impurity gas into the main gas each upon termination of growth of the thin-film.
